(19) United States
(12) Patent Application Publication
(10) Pub. No.: US 2014/0136134 A1
(43) Pub. Date: May 15, 2014

(54) METHOD AND APPARATUS FOR CALCULATING ELECTROMAGNETIC WAVE FROM ELECTRONIC DEVICE

(71) Applicant: ELECTRONICS AND TELECOMMUNICATIONS RESEARCH INSTITUTE, Daejeon (KR)

(72) Inventors: Soon-Soo OH, Daejeon (KR); Hyung Do CHOI, Daejeon (KR); Seung Keun PARK, Daejeon (KR); Young Seung LEE, Daejeon (KR); Sang Bong JEON, Daejeon (KR)

(73) Assignee: ELECTRONICS AND TELECOMMUNICATIONS RESEARCH INSTITUTE, Daejeon (KR)

(21) Appl. No.: 13/955,176

(22) Filed: Jul. 31, 2013

(30) Foreign Application Priority Data
Nov. 11, 2012 (KR) 10-2012-0133175

(51) Int. Cl. G01R 13/02

(52) U.S. Cl. CPC G01R 13/02
USPC 702/66

(57) ABSTRACT

A method of calculating an electromagnetic wave, includes measuring an electromagnetic wave emitted from an electronic device using an electromagnetic-wave scanner; and receiving the electromagnetic wave as input to detect an electromagnetic wave value in a proximity plane at a prescribed first distance from the electronic device. Further, the method includes calculating an electromagnetic wave at a point by a second distance from the electronic device using the electromagnetic wave value.

### CROSS-REFERENCE TO RELATED APPLICATION(S)

The present invention claims priority of Korean Patent Application No. 10-2012-0133175, filed on Nov. 22, 2012, which is incorporated herein by reference.

### FIELD OF THE INVENTION

The present invention relates to an apparatus for calculating an electromagnetic wave; and more particularly, to a method and apparatus for calculating an electromagnetic wave capable of acquiring an electromagnetic-wave measured value in a proximity plane separated by several centimeters or several tens of centimeters from an electronic device as an electromagnetic-wave calculation target using an electromagnetic-wave scanner and then accurately calculating an electromagnetic wave at a specific point separated by several tens of centimeters or several meters from the electronic device using the electromagnetic-wave measured value acquired in the proximity plane.

### BACKGROUND OF THE INVENTION

In recent years, with an increasing number of wireless/wired communication services, unwanted electromagnetic waves between various electronic devices or wireless communication devices increase, and accordingly, restrictions on an electromagnetic compatibility for minimizing the effect between electronic devices are increasing.

For an electromagnetic compatibility test, an electromagnetic-wave semi-anechoic chamber having a ground surface at the bottom is required, and the size thereof should be three meters or ten meters in accordance with a specified distance.

However, this size of electromagnetic-wave semi-anechoic chamber requires several tens of thousands dollars, and a turn table, a control device, and the like also costs over several tens of thousands dollars. These costs impose burden on small and medium-sized business. Accordingly, a electromagnetic compatibility test in a large semi-anechoic chamber causes an increase in development period and product cost and deterioration of productivity.

As an alternative to an expensive large semi-anechoic chamber, there is a near-field measurement method in which a measurement is made at a near distance between a three-wavelength and a ten-wavelength. However, since the wavelength of the operation frequency of the electromagnetic-wave compatibility test is a minimum of several meters, if a general near-field measurement method is utilized, a semi-anechoic chamber should be of large size. For example, if the operation frequency is 30 MHz, the wavelength is 10 m, and the three-wavelength becomes 30 m. Accordingly, the general near-field measurement method is not suitable as an alternative for the large semi-anechoic chamber.

As an alternative to an expensive large semi-anechoic chamber, there is a Fresnel zone measurement method, but this method is applied only to a medium-large antenna, such as a base station antenna or a satellite antenna, or electronic device. At this time, since the wavelength of the operation frequency of the electromagnetic-wave compatibility test is a minimum of several meters, and a general electronic device is of small size, the Fresnel zone measurement method is not suitable as an alternative of the large semi-anechoic chamber.

### SUMMARY OF THE INVENTION

In view of the above, the present invention provides a method and apparatus for calculating an electromagnetic wave capable of acquiring an electromagnetic-wave measured value in a proximity plane separated by several centimeters or several tens of centimeters from an electronic device as electromagnetic-wave calculation target using an electromagnetic-wave scanner and then accurately calculating an electromagnetic wave at a specific point separated by several tens of centimeters or several meters from the electronic device using the electromagnetic-wave measured value acquired in the proximity plane.

In accordance with a first aspect of the present invention, there is provided a method of calculating an electromagnetic wave. The method includes measuring an electromagnetic wave emitted from an electronic device using an electromagnetic-wave scanner; receiving the electromagnetic wave as input to detect an electromagnetic wave value in a proximity plane at a prescribed first distance from the electronic device; and calculating an electromagnetic wave at a point by a second distance from the electronic device using the electromagnetic wave value.

Further, the calculating the electromagnetic wave may comprise restoring a source on the surface of the electronic device using the electromagnetic wave value; generating a complex source from the restored source; and calculating an electromagnetic wave value at a point by the second distance from the electronic device using the complex source.

Further, the generating a complex source may comprise, after the source is restored, when there is a vertical component on a bottom surface of the electronic device, adding a radiation source of a vertical component at a position symmetrical to the bottom surface; and when there is a horizontal component on the bottom surface of the electronic device, adding a radiation source of a horizontal component at a position symmetrical to the bottom surface.

Further, the electromagnetic wave value may be the strength and phase of the electromagnetic wave.

Further, the source may be an emission source or a current source of the electronic device.

In accordance with a second aspect of the present invention, there is provided an apparatus for calculating an electromagnetic wave. The apparatus includes: an electromagnetic-wave scanner configured to move a probe for measuring an electromagnetic wave emitted from an electronic device to the surface of the electronic device; an electromagnetic-wave detector configured to receive an electromagnetic wave measured by the probe as input and detect an electromagnetic wave value in a proximity plane at a prescribed first distance from the electronic device; and an electromagnetic-wave converter configured to calculate an electromagnetic wave value at a point separated by a second distance from the electronic device using the detected electromagnetic wave value.

Further, the electromagnetic-wave converter may be configured to restore a source on the surface of the electronic device using the electromagnetic wave value, generate a complex source from the restored source, and calculate an electromagnetic wave at the point separated by the second distance from the electronic device using the complex source.

Further, the electromagnetic-wave converter may be configured to, after the source is restored, add a radiation source of a vertical component at a position symmetrical to a bottom when there is a vertical component on the bottom surface of the electronic device, and add a radiation source of a horizontal component at a position symmetrical to the bottom surface when there is a horizontal component on the bottom surface, to thereby generate the complex source.

Further, the electromagnetic-wave scanner may have two probes for measuring an electromagnetic wave from the electronic device, one of the probes measures an electromagnetic wave while moving on the surface of the electronic device, and the other probe is stationary.

In accordance with the present invention, in calculating an electromagnetic wave from an electronic device, an electromagnetic-wave measured value is acquired in a proximity plane separated by several centimeters or tens of centimeters from an electronic device as an electromagnetic-wave calculation target using an electromagnetic-wave scanner and then an electromagnetic wave at a specific point separated by tens of centimeters or several meters from the electronic device using the electromagnetic-wave measured value acquired in the proximity plane.

That is, in accordance with the present invention, even if a large semi-anechoic chamber is not provided, it is possible to accurately calculate an electromagnetic wave at a specific point separated from an electronic device using a relatively small electromagnetic-wave scanner. Furthermore, in accordance with the present invention, if an electromagnetic-wave scanner is provided in a development and production field, since it is not necessary to move a product between the development and production field and the large semi-anechoic chamber, it is possible to reduce the development and production time of an electronic device product, to reduce production cost per unit, thereby improving price competitiveness.

### BRIEF DESCRIPTION OF THE DRAWINGS

The above and other objects and features of the present invention will become apparent from the following description of the embodiments given in conjunction with the accompanying drawings, in which:

FIG. 1 is a detailed block diagram of an apparatus for calculating an electromagnetic wave in accordance with an embodiment of the present invention;

FIG. 2 is a control flow diagram illustrating a process of calculating an electromagnetic wave in accordance with the embodiment of the present invention; and

FIG. 3 is a diagram illustrating an electromagnetic wave measurement graph by distance from an electronic device in the apparatus for calculating an electromagnetic wave in accordance with the embodiment of the present invention.

### DETAILED DESCRIPTION OF THE EMBODIMENTS

In the following description of the present invention, if the detailed description of the already known structure and operation may confuse the subject matter of the present invention, the detailed description thereof will be omitted. The following terms are terminologies defined by considering functions in the embodiments of the present invention and may be changed operators intend for the invention and practice. Hence, the terms need to be defined throughout the description of the present invention.

Hereinafter, the embodiments of the present invention will be described in detail with reference to the accompanying drawings. In the following description, well-known functions or constitutions will not be described in detail if they would unnecessarily obscure the embodiments of the invention. Further, the terminologies to be described below are defined in consideration of functions in the invention and may vary depending on a user's or operator's intention or practice. Accordingly, the definition may be made on a basis of the content throughout the specification.

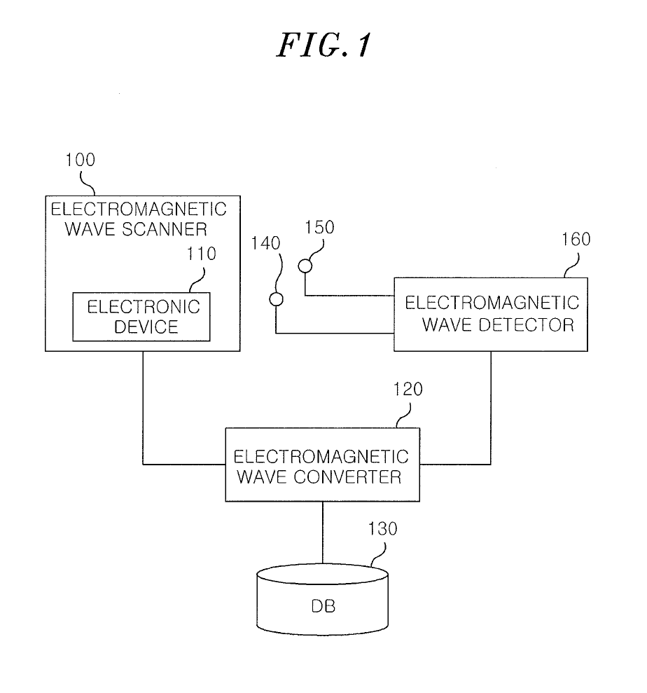

FIG. 1 is a detailed block diagram of an apparatus for calculating an electromagnetic wave in accordance with an embodiment of the present invention. The apparatus for calculating an electromagnetic wave includes an electromagnetic-wave scanner 100, probes 140 and 150, an electromagnetic-wave detector 160, and an electromagnetic-wave converter 120.

Hereinafter, the operation of each component of the apparatus for calculating an electromagnetic wave in accordance with the embodiment of the present invention will be described in detail with reference to FIG. 1.

First, the electromagnetic-wave scanner 100 is a device which measures an electromagnetic wave emitted from an electronic device 110. The electromagnetic-wave scanner 100 has an internal space where the electronic device 110 is loaded, and includes the probes 140 and 150 which measure an electromagnetic wave emitted from the surface of the electronic device 110. That is, the electromagnetic-wave scanner 100 measures an electromagnetic wave emitted from the electronic device 110 at a point relatively closely separated by several centimeters or tens of centimeters from the electronic device 110 using the probes 140 and 150.

In this case, since the electronic device 110 has an internal signal source, only the strength value of the electromagnetic wave can be measured. Accordingly, as shown in FIG. 1, the electromagnetic-wave scanner 100 uses the two probes 140 and 150 so as to measure the strength value and the phase value necessary for near-field near-field conversion or near-field to far-field conversion on an electromagnetic wave. One of the probes 140 and 150 measures an electromagnetic wave while moving on the surface of the electronic device 110, and the other probe is stationary.

The electromagnetic-wave detector 160 receives the electromagnetic wave to be measured by the probes 140 and 150 of the electromagnetic-wave scanner 100 as input and detects an electromagnetic wave value in a proximity plane at a prescribed first distance of several centimeters or tens of centimeters close to the electronic device 110. The electromagnetic wave value to be detected is the strength value and the phase value of the electromagnetic wave, and the detected electromagnetic wave value is stored in a database (DB) 130 of the electromagnetic-wave converter 120.

The electromagnetic-wave converter 120 performs a near-field to near-field conversion or a near-field to far-field conversion using the electromagnetic wave value actually measured in the proximity plane at the first distance from the electronic device 110 by the electromagnetic-wave detector 160 to calculate an electromagnetic wave value at a specific point separated at a prescribed second distance of tens of centimeters or several meters relatively far from the electronic device 110.

In other words, the electromagnetic-wave converter 120 restores a source, such as an emission source or a current source, on the surface of the electronic device using the electromagnetic wave value, generates a complex source from the restored source, and calculates the electromagnetic wave at a point by the second distance from the electronic device 110 using the complex source. In a process of generating the complex source from the restored source, on the assumption that the bottom surface of the space where the electronic device is located is a metallic surface, the electromagnetic-wave converter 120 adds a radiation source of a vertical component in the same direction at a position symmetrical to the bottom surface when there is a vertical component on the bottom surface of the electronic device 110, and adds a radiation source of a horizontal component in an opposite direction at a position symmetrical to the bottom surface when there is a horizontal component on the bottom surface, thereby generating a complex source.

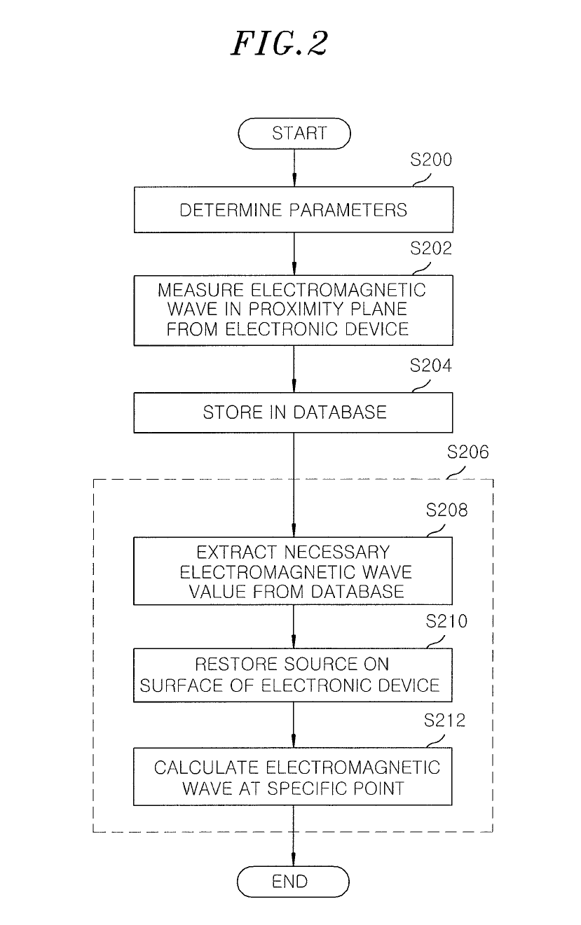

FIG. 2 is a control flow diagram of a process to calculate an electromagnetic wave at a specific point using an electromagnetic-wave measured value acquired at a near distance in the apparatus for calculating an electromagnetic wave in accordance with the embodiment of the present invention. Hereinafter, the embodiment of the present invention will be described in detail with reference to FIGS. 1 and 2.

First, the parameters necessary for electromagnetic wave calculation are determined, in an operation S200. These parameters are parameters for electromagnetic wave measurement in a proximity plane separated by the prescribed first distance from the electronic device 110, and include the distance at which an electromagnetic wave is measured, the frequency, the area of the proximal plane, the interval between measurement points, and the like. For example, the values of the parameters are set such that the frequency is 500 MHz, the distance from the electronic device is 2 cm, the area of the proximal plane is 180 mm in the horizontal direction and 180 mm in the vertical direction, the interval between measurement points is 9 mm, and the like. The parameter values are stored in the database 130 of the electromagnetic-wave converter and used to measure an actual electromagnetic wave value at a near distance from the electronic device 110 in the electromagnetic-wave detector 160.

Next, when the parameters necessary for the electromagnetic wave calculation are determined, the electromagnetic-wave detector 160 of the apparatus for calculating an electromagnetic wave measures an electromagnetic wave in a proximity plane from the electronic device 110 using the electromagnetic-wave scanner 100, in an operation S202. More specifically, the electromagnetic-wave detector 160 receives the electromagnetic wave measured by the probes 140 and 150 of the electromagnetic-wave scanner 100 as input and detects an electromagnetic wave value in a proximity plane at a prescribed first distance of several centimeters or tens of centimeters close to the electronic device 110. In this case, the electromagnetic wave value is the strength value and the phase value of the electromagnetic wave, and the detected electromagnetic wave value is stored in the database 130 of the electromagnetic-wave converter 120, in an operation S204.

Consequently, the electromagnetic-wave converter 120 reads the electromagnetic wave value actually measured in the proximity plane separated by the first distance from the electronic device 110 from the database 130 by the electromagnetic-wave detector 160, and performs near-field to near-field conversion or near-field to far-field conversion to calculate an electromagnetic wave value at a specific point by a prescribed second distance of tens of centimeters or several meters relatively far from the electronic device, in an operation S204.

In other words, the electromagnetic-wave converter 120 converts an electromagnetic wave value actually measured at a point separated by the first distance from the electronic device to an electromagnetic wave value at a specific point separated by the second distance greater than the first distance relatively far from the electronic device. In this regard, the distance may be within a near-field region or a far-field region depending on the size and frequency of the electronic device.

Hereinafter, the operation of the near-field to near-field conversion or near-field or far-field conversion in the electromagnetic-wave converter will be described separately in detail.

First, the electromagnetic-wave converter 120 extracts a necessary electromagnetic wave value from the database 130, in an operation S208. The extracted electromagnetic wave is substituted in a following Equation 1 to restore a source on the surface of the electronic device, in an operation S210.

$${H}_{x} = \frac{1}{4 π} \int {\int }_{S} ( z - {z}^{′} ) {J}_{y} \frac{1 + j β R}{{R}^{3}} {e}^{- j β R} d {x}^{′} d {y}^{′} \\ {H}_{y} = \frac{1}{4 π} \int {\int }_{S} - ( z - {z}^{′} ) {J}_{x} \frac{1 + j β R}{{R}^{3}} {e}^{- j β R} d {x}^{′} d {y}^{′} \qquad Equation 1$$

Referring to Equation 1, the measured electromagnetic wave values are Hₓ and H_{y}, the restored sources are Jₓ and J_{y} and all of them are in a matrix form. R is an electromagnetic wave measurement distance, and β is a propagation constant. x′, y′ and z′ are the coordinates of a source on the electronic device, and x, y and z are the coordinates of an electromagnetic wave measurement point. s lateral to an integral sign denotes a plane of a source. At this time, the electromagnetic wave value measured in Equation 1 and the values other than a source are expressed in a matrix form, and matrix calculation is performed.

After a source is restored in the above-described manner, the electromagnetic-wave converter 120 calculates an electromagnetic wave at a specific point separated by a specific distance, such as the second distance, from the electronic device 110 from the Equation 1, in an operation S212. At this time, in the Equation 1, Jₓ and J_{y} are the values restored in the electromagnetic-wave converter 120, and Hₓ and H_{y} are the electromagnetic wave values at a specific point to be calculated. All other values are expressed in a matrix form and matrix calculation is performed.

Meanwhile, since a facility to which the present invention is applied is a semi-anechoic chamber having a metal bottom surface, in restoring a source on the surface of the electronic device using the Equation 1 in the electromagnetic-wave converter, a theory of image is applied to a source to be restored. The theory of image can be used for the purpose of removing the metallic bottom surface.

That is, for example, when there is a vertical component on the metal bottom surface, it is assumed that there is further a radiation source of a vertical component in the same direction at a position symmetrical to the bottom surface, and the metallic bottom surface can be removed. When there is a horizontal component on the metal bottom surface, it is assumed that there is a further a radiation source of a horizontal component in an opposite direction at a position symmetrical to the bottom surface, and the metallic bottom surface can be removed.

As described above, the electromagnetic-wave converter 120 applies the theory of image to the restored source to generate to a complex source, and calculates the Equation 1 using the generated complex source. With this sequence of operations, an electromagnetic wave at a specific point can be calculated.

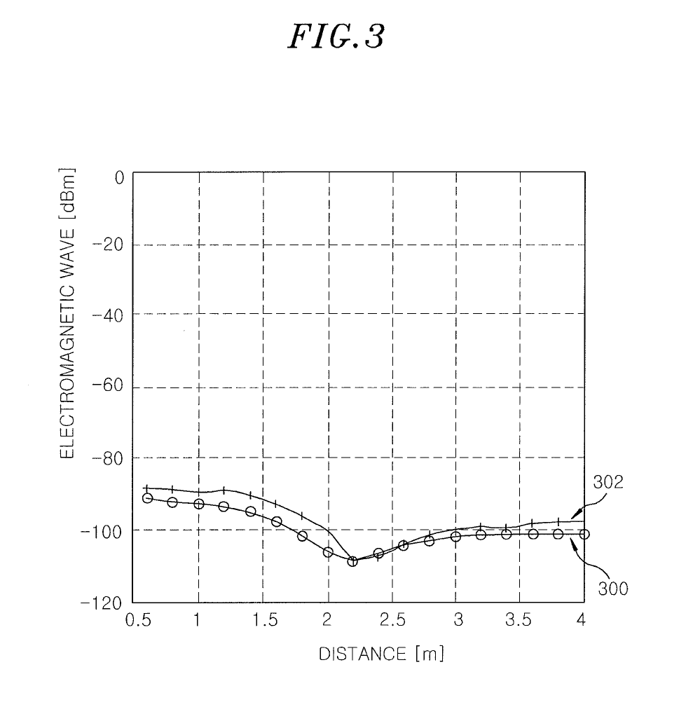

FIG. 3 shows the calculation result of an electromagnetic wave at a specific point separated by several meters from an electromagnetic wave measured value acquired at a point separated by several centimeters from an electronic device in accordance with the embodiment of the present invention.

In the embodiment of the present invention, a form in which a signal source is connected to a ring antenna is selected as the electronic device 110 has been described. The frequency is 500 MHz, and the electromagnetic wave value is measured in a plane separated by 2 cm from the electronic device. A measurement region is 180 mm in the horizontal direction and 180 mm in the vertical direction, and the interval between measurement points is 9 mm. An electromagnetic wave value is measured using the parameters, a source is then restored, and an electromagnetic wave is calculated in accordance with the distance from the electronic device 110.

In order to verify accuracy of the conversion method, a measurement was conducted in accordance with the distance from the electronic device 110 from 0.6 m to 4 m at an interval of 0.2 m.

FIG. 3 shows an electromagnetic wave value under the above-described conditions. As shown in FIG. 3, it can be observed that an electromagnetic wave value 300 converted in the embodiment of the present invention and an electromagnetic wave value 302 measured directly in a large semi-anechoic chamber of the related art are similar.

As described above, in accordance with the present invention, in calculating an electromagnetic wave from an electronic device, an electromagnetic-wave measured value is acquired in a proximity plane separated by several centimeters or tens of centimeters from an electronic device as an electromagnetic-wave calculation target using an electromagnetic-wave scanner and then an electromagnetic wave at a specific point separated by tens of centimeters or several meters from the electronic device using the electromagnetic-wave measured value acquired in the proximity plane. That is, in accordance with the present invention, even if a large semi-anechoic chamber is not provided, it is possible to accurately calculate an electromagnetic wave at a specific point separated from an electronic device using a relatively small electromagnetic-wave scanner. Furthermore, in accordance with the present invention, if an electromagnetic-wave scanner is provided in a development and production field, since it is not necessary to move a product between the development and production field and the large semi-anechoic chamber, it is possible to reduce the development and production time of an electronic device product, to reduce production cost per unit, thereby improving price competitiveness.

While the invention has been shown and described with respect to the embodiments, the present invention is not limited thereto. It will be understood by those skilled in the art that various changes and modifications may be made without departing from the scope of the invention as defined in the following claims.

What is claimed is:

1. A method of calculating an electromagnetic wave, the method comprising:
measuring an electromagnetic wave emitted from an electronic device using an electromagnetic-wave scanner;
receiving the electromagnetic wave as input to detect an electromagnetic wave value in a proximity plane at a prescribed first distance from the electronic device; and
calculating an electromagnetic wave at a point by second distance from the electronic device using the electromagnetic wave value.

2. The method of claim 1, the calculating the electromagnetic wave comprises:
restoring a source on the surface of the electronic device using the electromagnetic wave value;
generating a complex source from the restored source; and
calculating an electromagnetic wave value at a point by the second distance from the electronic device using the complex source.

3. The method of claim 2, wherein the generating a complex source comprises:
after the source is restored, when there is a vertical component on a bottom surface of the electronic device, adding a radiation source of a vertical component at a position symmetrical to the bottom surface; and
when there is a horizontal component on the bottom surface of the electronic device, adding a radiation source of a horizontal component at a position symmetrical to the bottom surface.

4. The method of claim 1, wherein the electromagnetic wave value is the strength and phase of the electromagnetic wave.

5. The method of claim 2, wherein the source an emission source or a current source of the electronic device.

6. An apparatus for calculating an electromagnetic wave, the apparatus comprising:
an electromagnetic-wave scanner configured to move a probe for measuring an electromagnetic wave emitted from an electronic device to the surface of the electronic device;
an electromagnetic-wave detector configured to receive an electromagnetic wave measured by the probe as input and detect an electromagnetic wave value in a proximity plane at a prescribed first distance from the electronic device; and
an electromagnetic-wave converter configured to calculate an electromagnetic wave value at a point separated by a second distance from the electronic device using the detected electromagnetic wave value.

7. The apparatus of claim 6, wherein the electromagnetic-wave converter is configured to restore a source on the surface of the electronic device using the electromagnetic wave value, generate a complex source from the restored source, and calculate an electromagnetic wave at the point separated by the second distance from the electronic device using the complex source.

8. The apparatus of claim 7, wherein the electromagnetic-wave converter is configured to, after the source is restored, add a radiation source of a vertical component at a position symmetrical to a bottom when there is a vertical component on the bottom surface of the electronic device, and add a radiation source of a horizontal component at a position symmetrical to the bottom surface when there is a horizontal component on the bottom surface, to thereby generate the complex source.

9. The apparatus of claim 6, wherein the electromagnetic-wave scanner has two probes for measuring an electromagnetic wave from the electronic device, one of the probes measures an electromagnetic wave while moving on the surface of the electronic device, and the other probe is stationary.
